(19) United States
(12) Patent Application Publication
(10) Pub. No.: US 2008/0157335 A1
(43) Pub. Date: Jul. 3, 2008

(54) Strip patterned transmission line

(76) Inventors: Jia Miao Tang, Pudong (CN); Xiang Yin Zeng, Waigaoqiao (CN); Dao Qiang Lu, Chandler, AZ (US); Jiang Qi He, Gilbert, AZ (US)

Correspondence Address: INTEL/BLAKELY, 1279 OAKMEAD PARKWAY, SUNNYVALE, CA, 94085-4040, US

(21) Appl. No.: 11/648,421

(22) Filed: Dec. 28, 2006

(51) Int. Cl. H01L 23/52; H01L 21/4763

(52) U.S. Cl. 257/690; 438/618; 257/E23.141; 257/E21.495

(57) ABSTRACT

A semiconductor package has a substrate. The substrate comprises a set of interconnects. An dielectric material may be provided under one or more of the interconnects to adjust the impedance of transmission line.

### BACKGROUND

In order to achieve a desirable band width and/or data rate, interconnect density are increased. However, the increased density may increase transmission line impedance associated with an interconnect and may result in a cross talk among interconnects.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 is a schematic diagram of an embodiment of a package.

FIG. 2 is a schematic diagram of an embodiment of a computer system.

FIGS. 3A and 3B are schematic diagrams of an embodiment of a method that may be used to provide a dielectric material in a substrate of the package of FIG. 1.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

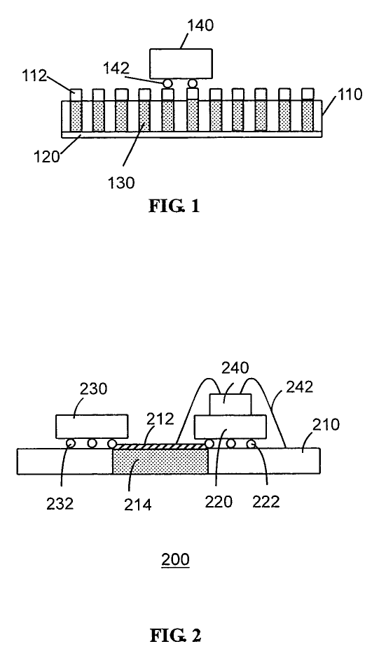

FIG. 1 illustrates an exemplary embodiment of a semiconductor package 100. In one embodiment, the package 100 may comprise a substrate 110. In one embodiment, the substrate 110 may be provided on a ground plate or plane 120; however, in some embodiments, the ground plate 120 may not be required. In another embodiment, the substrate 110 may comprise the ground plate 120. For example, the ground plate 120 may be a layer of the substrate 110. One example of the substrate 110 may comprise a printed circuit board (PCB) or a printed wiring board (PWB); however, any other suitable substrate may be utilized, including flex substrates such as folded flex substrates or flexible polyimide tape, laminate substrates such as bismaleimide triazine (BT) substrates, buildup substrates, ceramic substrates, flame retardant (FR-4) substrate, or tape automated bonding (TAB) tape material.

Referring to FIG. 1, in one embodiment, the substrate 110 may comprise a set of interconnects 112. For example, the set of interconnects 112 comprises one or more interconnects. In one embodiment, any suitable examples may be utilized for the interconnects 112, e.g., including metal traces, wirings, routings, metal layers, or bond pads. In another embodiment, a dielectric material 130 may be provided in the substrate 110. For example, the dielectric material 130 may be provided under each interconnect 112. In one embodiment, an interconnect 112 may provide a transmission line. The dielectric material 130 may be used to adjust impedance associated with each interconnect or transmission line. For example, the dielectric material 130 may be used to reduce impedance and/or crosstalk with regard to an interconnect or transmission line. In another embodiment, a dielectric material with a larger dielectric constant that is disposed under an interconnect may result in a lower impedance for the interconnect.

In one embodiment, the dielectric material 130 under an interconnect 112 may have a shape and/or width to match the interconnect 112. For example, the dielectric material 130 may have a shape such as a strip, a line, or a queue. In another embodiment, the dielectric material 130 under interconnects 112 may be used to improve far end crosstalk performance. In another embodiment, the dielectric material 130 may further be used to adjust, e.g., reduce near end crosstalk.

In one embodiment, any suitable materials may be utilized for the dielectric material 130, such as ferroelectric material, paraelectric material, ferroelectric filled polymer, other suitable polymers, or other dielectric materials. In one embodiment, the dielectric material having a larger dielectric constant may provide smaller transmission line impedance. In another embodiment, increasing a width of the dielectric material 130 under an interconnect 112 may reduce the transmission line impedance with regard to the interconnect 112. In another embodiment, increasing a depth of the dielectric material 130 in the substrate 110 may increase the impedance associated with an interconnect 112.

Referring to FIG. 1, the dielectric material 130 under an interconnect 112 may be separated from the dielectric material 130 under another interconnect 112. The substrate 110 may have a dielectric constant smaller than that of the dielectric material 130. In one embodiment, the substrate 110 may comprise a second dielectric material (not shown) that has a dielectric constant smaller than that of the dielectric material 130, e.g., Ajinomoto built-up film (ABF) type of materials. In one embodiment, the second dielectric material may be a prepreg material for the substrate 110.

In another embodiment, the dielectric materials 130 under different interconnects 112 may be separated from each other. For example, the adjacent dielectric material strips 130 or the dielectric materials 130 under adjacent interconnects 112 may not contact each other. However, in some embodiments, the dielectric materials 130 under different interconnects 112 may not be required to be separated. In yet another embodiment, the dielectric material 130 may be disposed at any depth of the substrate 110. In another embodiment, the dielectric material 130 may be provided directly beneath each interconnect 112. In another embodiment, the dielectric material 130 may extend an upper side of the substrate to a depth of the substrate.

Referring to FIG. 1, in one embodiment, a die 140 may be provided on the substrate 110. The die 140 may be coupled to the substrate 110 by bumps. In another embodiment, the die 140 may be a bump die. However, in some embodiments, the die 140 may be coupled to the substrate 110 by other interconnects, such as conductive protrusions, bond pads, vias, bond fingers, solder balls, or wire bonds. While FIG. 1 illustrates one die on the substrate 110, in some embodiments, more dies may be provided on the substrate 110. Examples of the package 100 may comprise flash memory, static random access memory (SDRAM), digital signal processor (DSP), application specific integrated circuit (ASIC), logic circuits, and/or any other circuits or devices. In yet another embodiment, a multi-layered substrate may be utilized.

FIG. 2 illustrates an embodiment of a computer system 200. In one embodiment, the computer system 200 may comprise a substrate 210. Referring to FIG. 2, a first control 220 may be provided on the substrate 210. Examples of the first control 220 may comprise a memory controller, a digital signal processor (DSP), a processor, logic circuit or any other control unit or device. For example, the first control 220 may comprise a CPU. A second control 230 may further be provided on the substrate 210. For example, the second control 230 may comprise a memory controller such as memory controller hub (MCH). As shown in FIG. 2, a memory 240 may be provided on the CPU 220. In one embodiment, any suitable memory devices may be utilized, such as NOR, NAND, dynamic random access memory (DRAM), or flash memory.

Referring to FIG. 2, CPU 220 and/or the memory controller 230 may be coupled to the substrate 210 by bumps, e.g., bumps 222 and 232. The CPU 220 may be coupled to the memory controller 230 by one or more interconnects 212 on the substrate 210. In one embodiment, dielectric material 214 may be provided in the substrate 210, e.g., under an interconnect 212. The dielectric material 214 may have a dielectric constant larger than that of the substrate 210. In another embodiment, the memory 240 may be coupled to one or more interconnects (not shown) on the substrate 210. The memory 240 may be wire bonded to the substrate 210. While FIG. 2 shows that the memory 240 may be provided on CPU 220, in some embodiments, the memory 240 may be provided on the substrate 210 to couple to the CPU 220 and/or the memory controller 230 by one or more interconnects (not shown) on the substrate 210. Dielectric material 214 may be provided under the one or more interconnects. In another embodiment, other interconnects may be utilized, such as bond pads or solder balls. In some embodiment, different chips, substrates, interconnects, memories, or arrangements may be utilized. In yet another embodiment, the dielectric material 214 provided under an interconnect 212 may be different from dielectric material provided under an interconnect (not shown) on the substrate 210 that couples to the memory 240.

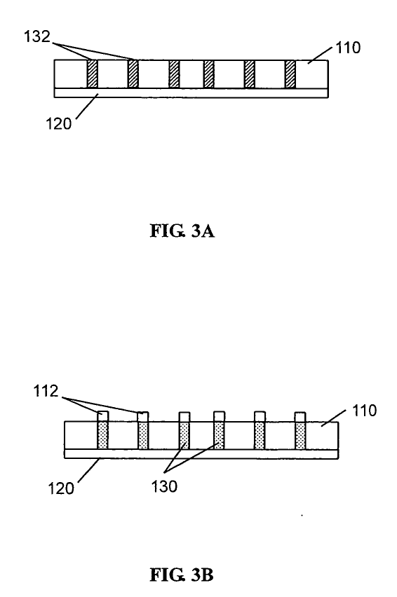

FIGS. 3A and 3C illustrates an embodiment of a method to embed the dielectric material 130 in the substrate 110. Referring to FIG. 3A, in one embodiment, the substrate 110 may be mounted to a ground plate 120; however, in some embodiments, the ground plate 120 may not be required. In another embodiment, a set of openings 132 may be provided in the substrate 110. The set of openings 132 may include one of more openings. In other embodiments, other empty spaces such as holes, cavities, gaps, slits, hollows may be utilized. In one embodiment, the openings 132 may be prepared by, e.g., drilling, punching, puncturing, piercing, etching, or any other hole-making methods. In another embodiment, the openings 132 may be formed via laser. In yet another embodiment, a patterned model (not shown) may be applied to the substrate 110 that may be flowable or in a liquid state to form the openings 132. The substrate 110 may further be cured. In one embodiment, the openings 132 may be shaped to match the interconnects 112. In another embodiment, a mask (not shown) for the interconnects 112 may be utilized to provide the openings 132.

Referring to FIG. 3B, the dielectric material 130 may be filled or deposited in each opening 132. An interconnect 112 may be provided on respective dielectric material 130. In another embodiment, the substrate 110 may comprise a dielectric constant that may be smaller than that of the dielectric material 130. For example, two adjacent strips of dielectric material 130 may be separated from each other; however, this may not be required. In one embodiment, the substrate 110 may comprise a second dielectric material (not shown) that may comprise a smaller dielectric constant than that of the dielectric material 130, such as ABF type of materials.

While the methods of FIGS. 3A and 3B are illustrated to comprise a sequence of processes, the method in some embodiments may perform illustrated processes in a different order. Further, while the embodiments of FIGS. 1, 2, 3A and 3B are illustrates to comprise a certain number of dies, interconnects, substrates, interconnects, chips, some embodiments may apply to a different number.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A semiconductor package, comprising:
a substrate having one or more interconnects; and
a first dielectric material provided under one or more of the interconnects.

2. The semiconductor package of claim 1, wherein the first dielectric material has a dielectric constant larger than that of the substrate.

3. The semiconductor package of claim 1, wherein the first dielectric material under an interconnect is separated from the first dielectric material under another interconnect.

4. The semiconductor package of claim 1, wherein the first dielectric materials under adjacent interconnects are separated from each other.

5. The semiconductor package of claim 1, wherein the substrate comprises a second dielectric material that has a dielectric constant smaller than that of the first dielectric material.

6. The semiconductor package of claim 1, wherein the first dielectric material comprises one or more from a group of ferroelectric material, paraelectric material, ferroelectric filled polymer.

7. The semiconductor package of claim 1, wherein the first dielectric material provided under the interconnect is to adjust impedance associated with the interconnect.

8. A method, comprising:
providing one or more interconnects on a substrate, and
providing a first dielectric material in the substrate, wherein the first dielectric material is provided under one or more of the interconnects.

9. The method of claim 8, comprising:
providing one or more openings in the substrate for the first dielectric material.

10. The method of claim 8, wherein a mask for the one or more interconnects is used to provide the first dielectric material.

11. The method of claim 8, comprising:
applying a patterned model to the substrate that is flowable to form the one or more openings.

12. The method of claim 8, wherein the substrate comprise a second dielectric material that separates the first dielectric materials under adjacent interconnects are separated from each other.

13. The method of claim 8, wherein the substrate comprises a second dielectric material that has a dielectric constant smaller than that of the first dielectric material.

14. The method of claim 8, wherein the first dielectric material has a dielectric constant larger than that of the substrate.

15. A computer system, comprising:
a substrate,
a first control coupled to the substrate, and
a second control coupled to the first control by a first interconnect on the substrate, wherein a first dielectric material is provided under the first interconnect.

16. The computer system of claim 15, comprising:
a memory coupled to the substrate, wherein the memory is coupled to the first control by a second interconnect, under which the first dielectric material is provided.

17. The computer system of claim 15, comprising:
a memory provided on the first control, wherein the memory is coupled to the substrate by wire bonds.

18. The computer system of claim 15, wherein the first control comprises a CPU, the second control comprises a memory controller.

19. The computer system of claim 15, wherein the first dielectric material has a dielectric constant larger than that of the substrate.

20. The computer system of claim 16, wherein the first dielectric material under the first interconnect is separated from the first dielectric material under the second interconnect.

21. The computer system of claim 15, wherein the substrate comprises a second dielectric material that has a dielectric constant smaller than that of the first dielectric material.
